(19) United States
(12) Patent Application Publication
(10) Pub. No.: US 2007/0257339 A1
(43) Pub. Date: Nov. 8, 2007

(54) SHIELD STRUCTURES

(75) Inventors: Hsien-Wei Chen, Sinying City (TW); Victor C. Y. Chang, Hsinchu City (TW); Tzu-Jin Yeh, Hsinchu City (TW); Shu-Ying Cho, Hsin-Chu City (TW); Keh-Jeng Chang, Hsinchu City (TW); Kwang-Leei Young, Taipei (TW)

Correspondence Address: DUANE MORRIS LLP;IP DEPARTMENT (TSMC), 30 SOUTH 17TH STREET, PHILADELPHIA, PA, 19103-4196, US

(73) Assignee: Taiwan Semiconductor Manufacturing Co., Ltd., Hsin-Chu (TW)

(21) Appl. No.: 11/382,202

(22) Filed: May 8, 2006

(51) Int. Cl. H01L 23/62

(52) U.S. Cl. 257/665

(57) ABSTRACT

Shield structures are provided. A first and second shield lines are formed over a substrate and coupled with a first voltage. A conductive line is formed between the first and the second shield lines, and coupled with a second voltage. The first shield layer is formed over the substrate and coupled to the first and the second shield lines via at least one first conductive structure.

### BACKGROUND OF THE INVENTION

1. Field of the Invention

The present invention relates to shield structures and, more particularly, relates to shield structures of semiconductor circuits.

2. Description of the Related Art

Complementary Metal Oxide Semiconductor (CMOS) technology has been frequently applied in manufacturing integrated circuits (IC). With the advance of CMOS technology, the miniaturization of CMOS devices based upon a scaling rule is used in a semiconductor device to achieve high integration density and high-speed operation. In addition to the miniaturization of the scale of the CMOS devices, multiple-level interconnect technology is also used to increase the high density of integration. However, the miniaturization of multiple-level interconnects may cause cross-talk between metal lines.

FIGS. 1A and 1B are a cross-sectional view and a top plan view of a prior art interconnect structure. FIG. 1A is the cross-sectional view of the structure of FIG. 1B along section line 1A-1A shown in FIG. 1B.

Beginning with FIG. 1A, two metal lines 110 and 120 are on the substrate 100. The circles 130 and 140 represent magnetic fields resulting from electrical currents flowing in the metal lines 110 and 120. The arrows on the circles 130 and 140 represent the magnetic field directions. Referring to FIG. 1B, the arrows 150 and 160 represent the current flow directions within the metal lines 110 and 120, respectively. Due to the different current flow directions 150 and 160, the magnetic field direction of the metal line 110 is counter-clockwise, and the magnetic field direction of the metal line 120 is clockwise (when viewed from the same direction). The magnetic fields 130 and 140 interfere with the current flowing within the metal lines 120 and 110, respectively. This phenomenon causes cross-talk between the metal lines 110 and 120. It also affects electrical characteristics, such as impedance, of the interconnects. If the space between the metal lines 110 and 120 is reduced, the cross-talk phenomenon of the metal lines 110 and 120 becomes serious. Accordingly, this phenomenon normally exists in highly integrated semiconductor circuits.

U.S. Pat. No. 6,878,964 provides a tester for a semiconductor device. The tester includes a bottom ground pad structure, an intermediate ground pad structure, and a top layer. The bottom ground pad structure is electrically connected to a substrate. The bottom ground pad structure includes a bottom signal shield plate. The intermediate ground pad structure is electrically connected to the bottom ground pad structure. The intermediate ground pad structure is located over the bottom ground pad structure. The top layer is located over the intermediate ground pad structure. The top layer includes a device under test (DUT), a ground probe pad, a signal probe pad, and leads. The DUT is electrically connected to the ground probe pad and the signal probe pad via the leads. The ground probe pad is electrically connected to the intermediate ground pad structure. The signal probe pad is located over the bottom signal shield plate.

Mezhiba et al. published a paper titled “Inductive Characteristics of Power Distribution Grids in High Speed Integrated Circuits” in Proceedings of the International Symposium on Quality Electronic Design 2002 (ISQED'02). In this paper, the inductance extraction program FastHenry is used to evaluate the inductive properties of grid structured interconnect. In power distribution grids with alternating power and ground lines, the inductance is shown to vary linearly with grid length and inversely linearly with the number of lines in the grid. The inductance is also relatively constant with frequency in these grid structures. These properties provide estimates of the inductance of power grid structures with various dimensions.

Accordingly, improved shield structures are desired.

### SUMMARY OF THE INVENTION

In some embodiments, a semiconductor structure comprises a first and second shield lines, at least one conductive line, and a first shield layer. The first and second shield lines are coupled with a first voltage over a substrate. The conductive line is coupled with a second voltage and configured between the first and the second shield lines. The first shield layer is coupled to the first and the second shield lines via at least one first shield structure over the substrate.

The above and other features of the present invention will be better understood from the following detailed description of the preferred embodiments of the invention that is provided in connection with the accompanying drawings.

### BRIEF DESCRIPTION OF THE DRAWINGS

Following are brief descriptions of the drawings. They only illustrate exemplary embodiments described below and the scope of the invention should not be limited thereto.

FIGS. 1A and 1B are a cross-sectional view and a top plan view of a prior art interconnect structure, and FIG. 1A is the cross-sectional view of the structure of FIG. 1B along section line 1A-1A.

FIGS. 2A-2F are cross-sectional views of exemplary shield structures.

FIG. 3 is a top view of an exemplary shield structure.

FIGS. 4A-4C are cross-sectional views showing an exemplary method of forming a shield structure.

FIG. 5 is a schematic drawing showing an exemplary application of a shield structure among inter-block circuits.

### DESCRIPTION OF THE PREFERRED EMBODIMENT

This description of the exemplary embodiments is intended to be read in connection with the accompanying drawings, which are to be considered part of the entire written description. In the description, relative terms such as “lower,” “upper,” “horizontal,” “vertical,” “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation.

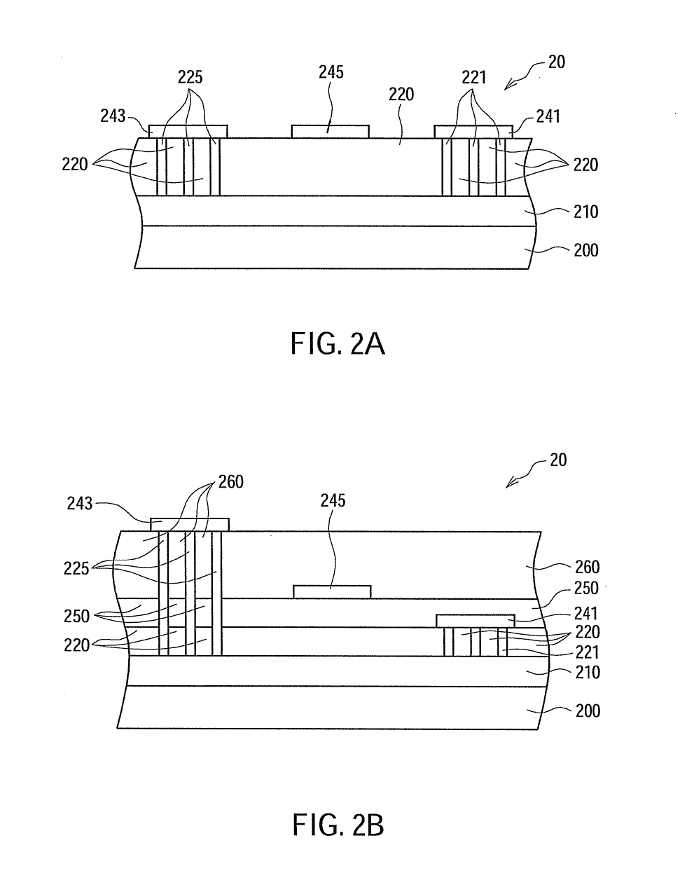

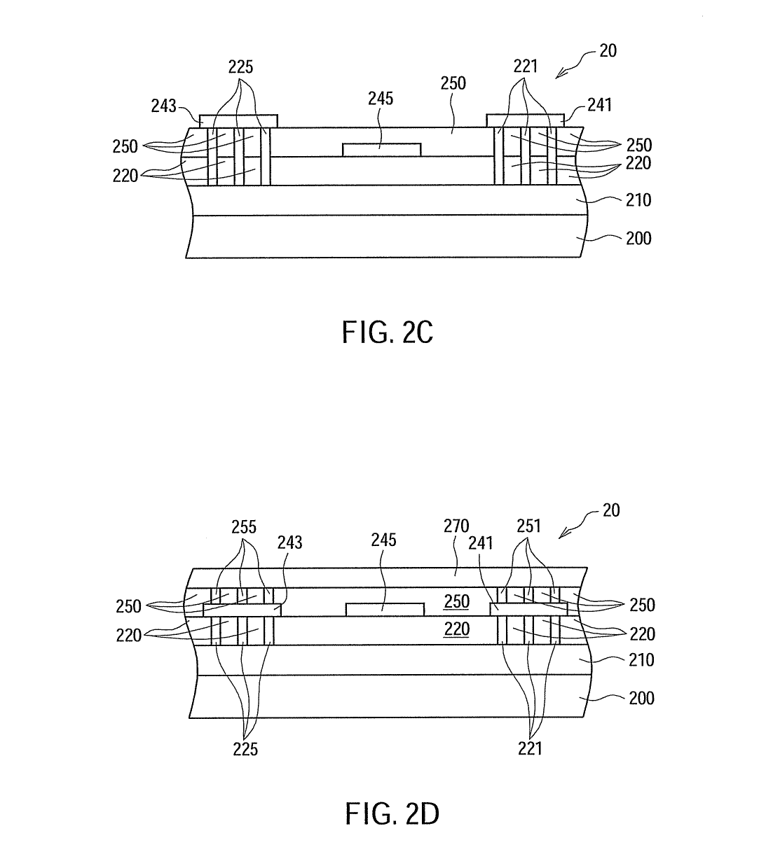

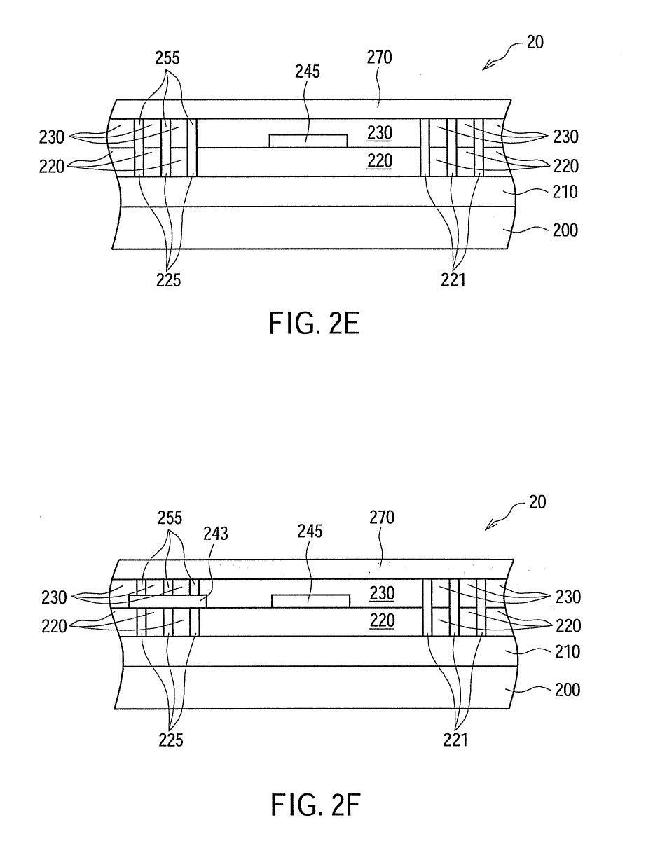

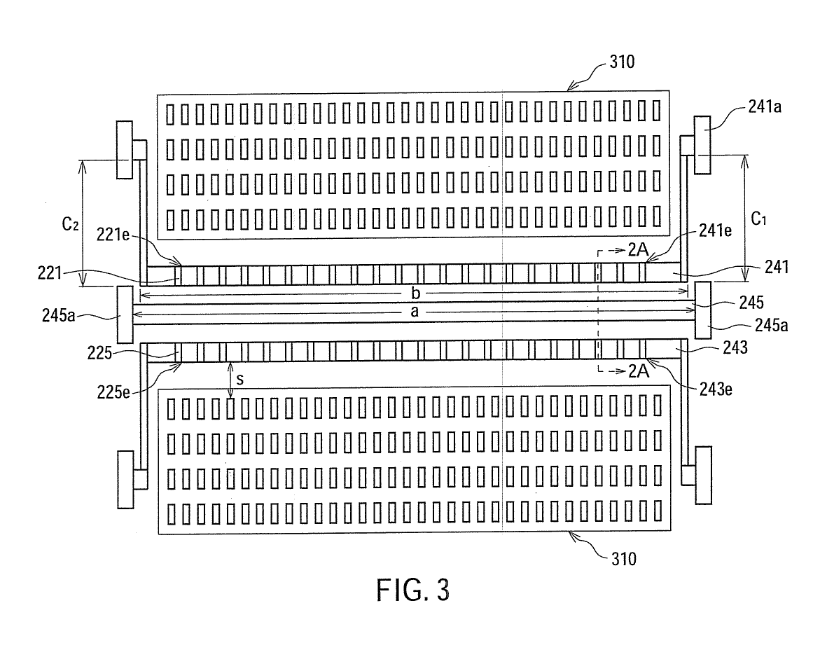

FIGS. 2A-2F are cross-sectional views of exemplary shield structures. FIG. 3 is a top view of an exemplary shield structure. To simplify these drawings, cross-hatching is omitted from FIGS. 2A-2F and 3.

FIG. 2A is a cross-sectional view of an exemplary shield structure 20 along section line 2A-2A of FIG. 3. In FIG. 2A, the first shield layer 210 is formed over the substrate 200. The substrate 200 can be, for example, a silicon substrate, a III-V compound substrate, a glass substrate, a printed circuit board (PCB) or any other substrate similar thereto. In addition, the substrate 200 may comprise various devices thereon to provide desired electrical operations. The first shield layer 210 comprises a sheet layer, a mesh layer, a plurality of strips or other structures which are capable of shielding a signal line from interference caused by other circuits. In some embodiments, the first shield layer 210 comprises a conductive layer made of aluminum (Al), copper (Cu), AlCu, aluminum alloy, copper alloy, iron alloy, cobalt ally, nickel alloy, polysilicon or other conductive materials.

The dielectric layer 220 is formed over the first shield layer 210. The dielectric layer 220 can be made of, for example, silicon oxide, silicon nitride, silicon oxy-nitride, low-k dielectric material layer or other materials that are adapted to isolate conductive layers. The first and second shield lines 241 and 243, respectively, and the conductive line 245 are formed over the dielectric layer 220. The conductive line 245 is made of aluminum (Al), copper (Cu), AlCu, polysilicon or other conductive materials. The first and second shield lines 241 and 243, respectively, are made of aluminum (Al), copper (Cu), AlCu, aluminum alloy, copper alloy, iron alloy, cobalt ally, nickel alloy, polysilicon or other conductive materials. The first and second shield lines 241 and 243, respectively, are coupled to the first shield layer 210 via the conductive structures 221 and 225. The conductive structures 221 and 225 comprise at least one via, a conductive line or a combination thereof which is made of Al, Cu, AlCu, Al alloy, Cu alloy, iron alloy, cobalt ally, nickel alloy, tungsten (W) or other conductive materials.

The first and second shield lines 241 and 243 are coupled to a first voltage, such as ground or a fixed voltage. The conductive line 245 is coupled to a second voltage which is same or different from the first voltage. The second voltage can be higher or lower than, or equal to the first voltage. The conductive line 245 can be a signal line, a power line, a ground line, a floating line or other line for routing of circuits. In this embodiment, the conductive line 245 serves as a signal line. In some embodiments, there are more than one conductive lines 245 between the first and the second shield lines 241 and 243, if the operations of the conductive lines 245 are not severely affected by each other. One skilled in the art can readily select the desired number of conductive lines 245 between the first and the second shield lines 241 and 243, for any given configuration based on the descriptions of embodiments set forth above.

In addition, the conductive line 245 is substantially as long as at least one of the first and the second shield lines 241 and 243 as shown in FIG. 3. For example, the length “a” of the conductive line 245 is substantially as long as the length “b” of the first shield line 241. In one embodiment, the first shield line 241 is connected to two additional line segments having “c1” and “c2,” respectively. The additional connected segments are added to allow the pads 241a to be offset from line 241, to prevent interference between the pads 241a of the first shield line 241 and the pads 245a of the conductive line 245. If there is no such interference between the pads 241a and 245a, the offset segments “c1” and “c2” can be eliminated. In some embodiments, the shield structure 20 including the shield lines 241 and 243 and the conductive line 245 is adapted to be coupled to and between inter-block circuits. A detailed description is provided below.

In the embodiment shown in FIG. 2A, the first shield layer 210 is below the first shield line 241, the second shield line 243 and the conductive line 245. Accordingly, the conductive line 245 is substantially “bottom-surrounded” (i.e., surrounded below and on the sides thereof) by the first and second shield lines 241 and 243, and the first shield layer 210. In other embodiments, the first shield layer 210 is above the first shield line 241, the second shield line 243 and the conductive line 245. As a result, the conductive line 245 is substantially “top-surrounded” (i.e., surrounded above and on the sides thereof) by the first and second shield lines 241 and 243, and the first shield layer 210.

In some embodiments, the shield layer 210 is a planar layer. In other embodiments, the shield layer 210 is a stripe (not shown). For such embodiments, the width of the first shield layer 210 is substantially equal to, or larger than, the distance from the outer edge 241e of the first shield line 241 to the outer edge 243e of the second shield line 243. In other embodiments, the width of the first shield layer 210 is substantial equal to, or larger than, the distance from the outer edge 221e of the conductive structure 221 to the outer edge 225e of the conductive structure 225. One skilled in the art can readily understand how to design variations of the structure of the first shield layer 210 in which the width of the first shield layer 210 accommodates the conductive structures 221 and 225 coupled to the first shield line 241 and the second shield line 243.

In the exemplary embodiment of FIG. 2A, the first shield line 241, the second shield line 243 and the conductive line 245 are co-planar. In some embodiments, as described below, not all of the shield lines 241 and 243 and the conductive line 245 are co-planar. Following are exemplary variations of the embodiment of FIG. 2A.

FIG. 2B is a cross-sectional view of another exemplary shield structure. Referring to FIG. 2B, the first shield line 241, the second shield line 243 and the conductive line 245 are not formed over the same layer. The first shield line 241 is formed over the surface of the dielectric layer 220. The second shield line 243 is formed over the surface of the dielectric layer 260. The conductive line 245 is formed between the shield lines 241 and 243, but over the surface of the dielectric layer 250. Accordingly, the first shield line 241, the first shield layer 210, the second shield line 243 and the conductive structures 221 and 225 are positioned at various locations around the conductive line 245 so as to substantially shield the conductive line 245. The shielding substantially reduces the inductance of the conductive line 245 by about 10% or more relative to another signal line without the first shield layer 210 and the conductive structure.

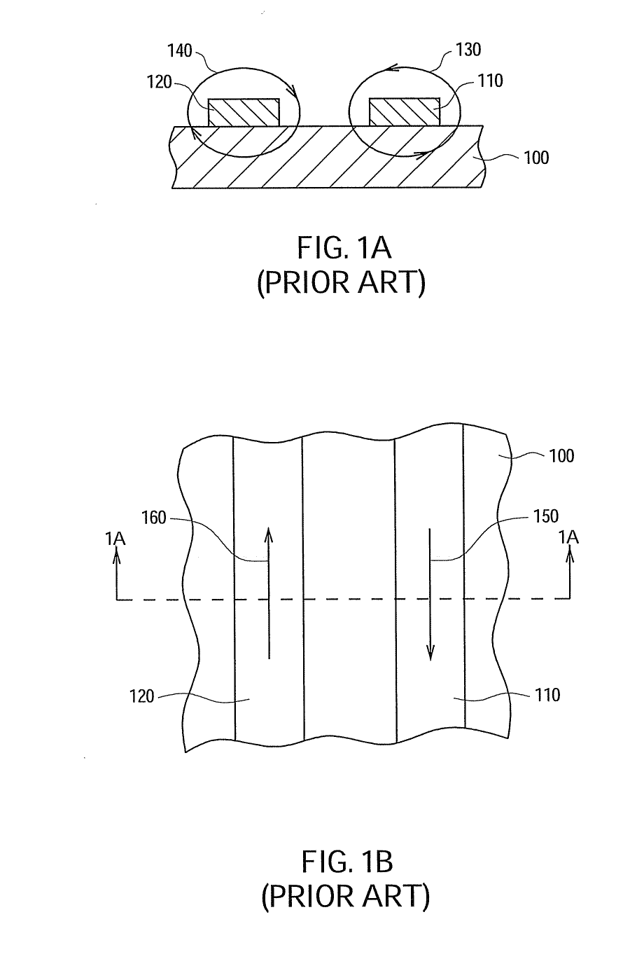

For example, if a 20-GHz signal is applied to the structure with shielding as shown in FIG. 2A, the inductance of the conductive line 245 simulated by FastHenry is about 0.496 nH/mm. If the same 20-GHz signal is applied to the conductive line 150 or 160 without shielding (as shown in FIG. 1), the inductance of the conductive line 150 or 160 is about 0.575 nH/mm, which is higher than 0.496 nH/mm by about 16%. The shield structure formed by the first shield line 241, the first shield layer 210, the second shield line 243 and the conductive structures 221 and 225 reduces the inductance by 16%. Accordingly, the inductance of the conductive line 245 is well controlled.

In other embodiments, the first shield line 241, the second shield line 243 and the conductive line 245 are formed over the surfaces of a plurality of dielectric layers which are not next to each other. For example, in some embodiments the first shield line 241 is formed over the surface of the bottom dielectric layer, the second shield line 243 is formed over the surface of the sixth dielectric layer, and the conductive line 245 is formed over the surface of the fourth dielectric layer. One skilled in the art can readily modify the shield structure 20 to accommodate a given set of positions of the first shield line 241, the second shield line 243 and the conductive line 245.

FIG. 2C is a cross-sectional view of an exemplary shield structure 20. The first and second shield lines 241 and 243 are formed over the surface of the dielectric layer 250, and the conductive line 245 is formed between the lines 241 and 243, but over the surface of the dielectric layer 220. The first and second shield lines 241 and 243 are formed to be co-planar. In other embodiments (not shown), the first and the second shield lines 241 and 243 are formed below the conductive line 245. As described above, the first shield line 241, the second shield line 243 and the conductive line 245 can be formed over the surfaces of a plurality of dielectric layers, which are not next to each other.

FIG. 2D is a cross-sectional view of an exemplary shield structure 20 with a second shield layer 270.

In FIG. 2D, the second shield layer 270 is formed over the structure of FIG. 2A. The second shield layer 270 is formed over, and coupled to, the first and second shield lines 241 and 243 via the conductive structures 251 and 255. In some embodiments, the properties of the second shield layer 270 are similar to those of the first shield layer 210 set forth above in connection with FIG. 2A. In some embodiments, the dielectric layer 250 is similar to the dielectric layer 220, and the structure and material of the conductive structures 251 and 255 are similar to those of the conductive structures 221 and 225. Detailed descriptions of these items are not repeated.

In FIG. 2D, the first and second shield lines 241 and 243, the first and second shield layers 210 and 270, and the conductive structures 221, 225, 251 and 255 substantially surround the conductive line 245. That is, the shielding substantially reduces an inductance of the conductive line 245 by about 10% or more, and enables better control of inductance.

FIG. 2E is a cross-sectional view of an exemplary shield structure without the first and second shield lines shown in FIG. 2D.

In FIG. 2E, the first and second shield layers 210 and 270, and the conductive structures 221 and 225 substantially surround the conductive line 245 without the first and the second shield lines 241 and 243 shown in FIG. 2D. Because the conductive line 245 is still surrounded by the shield layers 210 and 270, and conductive structures 221 and 225, the first and the second shield lines 241 and 243 may not be required to provide a sufficient level of shielding to maintain the crosstalk below a predetermined threshold.

FIG. 2F is a cross-sectional view of an exemplary shield structure without the first shield line shown in FIG. 2D.

Referring to FIG. 2F, the second shield line 243 is between and coupled to the first and the second shield layers 210 and 270. As a result, the first and the second shield layers 210 and 270, the second shield line 243 and the conductive structures 221, 225 and 255 substantially surround the conductive line 245 without the first shield line 241 shown in FIG. 2D.

Any of the variations described in connection with FIGS. 2A-2C can be practiced in combination with any of the embodiments shown in FIGS. 2D-2F. One skilled in the art can readily understand and modify these embodiments based upon the descriptions above to achieve a desired shield structure.

FIG. 3 is a top plan view of a shield structure 20 according to an exemplary embodiment.

Referring to FIG. 3, elements 221, 225, 241, 243 and 245 with numerals that are the same as those shown in FIG. 2A have the same structures and materials set forth above in connection with FIG. 2A. Detailed descriptions of these items are not repeated.

As shown in FIG. 3, in some embodiments, the shield structure 20 comprises at least one dummy pattern 310 adjacent to the first shield line 241 and/or the second shield line 243. The dummy patterns 310 comprise at least one dummy via, at least one dummy conductive line or a combination thereof, which is made of Al, Cu, AlCu, tungsten (W), aluminum alloy, copper alloy, iron alloy, cobalt ally, nickel alloy, polysilicon or other conductive materials. In some embodiments, the space between the dummy patterns 310 and the first and second shield lines 241 and 243 satisfies at least one feature size of the design rule. In one embodiment, the space between the dummy patterns 310 and the first and second shield lines 241 and 243 is larger than one feature size of the design rule, for example, 0.5 μm. The dummy patterns 310 help the manufacturing process to obtain the first shield line 241, the second shield line 243, and the conductive line 245 with a uniform thickness. Due to the thickness uniformity, the electrical characteristics of circuits with the shield structure 20 are more desirable. In some embodiments (not shown), the dummy patterns 310 are not required. In some embodiments (not shown), the first and second shield lines 241 and 243 can be non-continuous or comprise at least two portions. One skilled in the art can readily determine whether to add dummy patterns within the shield structure 20 and what shapes or how many dummy patterns should be added.

In some embodiments without the first and/or the second shield lines 241 and 243, the dummy patterns 310 are configured adjacent to the conductive structure 221, 225, 251 or 255 shown in FIG. 2D. The feature size space also should be followed for these embodiments.

Because the shield structure 20 is designed to prevent the worst coupling effect within circuits, the dimensions of the shield structure 20 corresponds to at least a minimum feature size determined by a design rule. Preferably, the dimensions of the shield structure 20 are substantially equal to feature sizes of design rule. For example, variations of the dimensions of the shield structure 20 is about ±10% minimum feature sizes of the design rule. By designing the shield structure 20 based upon the feature size, the dimensions of a shield structure 20 are substantially minimized. The feature size can be applied to test the worst condition at a specified location of the shield structure 20. It is not necessary that all dimensions of the shield structure 20 should meet all of the feature sizes determined by the design rule. For example, in some embodiments the shield structure 20 may comprise the feature sizes of the widths of the shield lines 241 and 243, but not the feature sizes of the space between the first shield line 241 and the conductive line 245, because the interference resulting from the space is not essential in these embodiments. In other embodiments, the shield structure 20 may only have a feature size corresponding to the space between the first shield line 241 and the conductive line 245 and between the second shield line 243 and the conductive line 245, but not the feature sizes of the widths of the first shield line 241 and the conductive line 245. One skilled in the art can readily select the desired feature sizes corresponding to the portion of a structure which has the worst signal crosstalk.

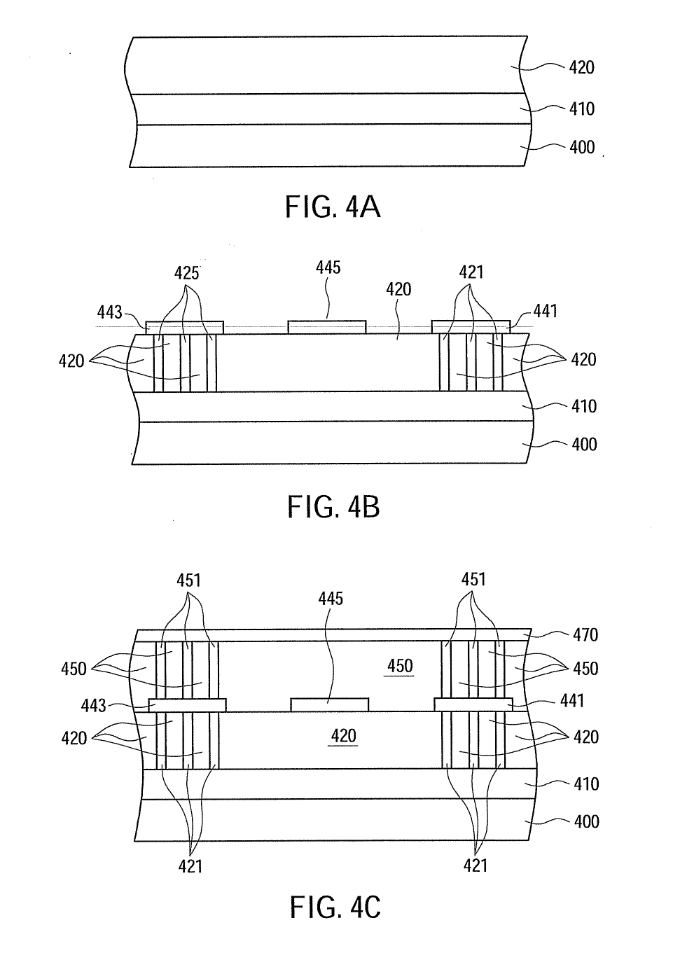

FIGS. 4A-4C are cross-sectional views showing a method of forming the exemplary shield structure of FIG. 2D. In FIGS. 4A-4C like items are indicated by reference numerals having the same value as in FIG. 2D, increased by 200. Thus, these items in FIGS. 4A-4C can be the same as corresponding items described above with reference to FIG. 2D, and a description of these items is not repeated. To simplify these drawings, cross-hatching is omitted from FIGS. 4A-4C.

FIG. 4A is a cross-sectional view of a semiconductor structure with a first shield layer 410 and a first dielectric layer 420 over a substrate 400.

In FIG. 4A, the first shield layer 410 and the first dielectric layer 420 are sequentially formed over the substrate 400. The first shield layer 410 and the first dielectric layer 420 can be formed by, for example, Chemical Vapor Deposition (CVD), Physical Vapor Deposition (PVD), Electro-Copper Plating (ECP) or other methods which are adapted to form thin film layers.

FIG. 4B is a cross-sectional view of a semiconductor structure with conductive structures within the first dielectric layer, and the first shield line, the second shield line and the conductive line over the first dielectric layer.

In FIG. 4B, via holes (not shown), in which the conductive structures 421 and 425 are formed, can be patterned by, for example, a photolithographic process and an etch process. The material of the conductive structures 421 and 425 is then filled within the via holes. The material of the conductive structures 421 and 425 above the surface of the first dielectric layer 420 is then removed by, for example, Chemical Mechanical Polish (CMP), etch back or other processes which are suitable for removing the material. The conductive structures 421 and 425 can be formed during the same or different processes. In a preferred embodiment, they are formed during the same process.

The material of the first shield line 441, the second shield line 443, and the conductive line 445 are formed over the first dielectric layer 420. The material of the first shield line 441, the second shield line 443 and the conductive 445 is then patterned by, for example, a photolithographic process and an etch process. In some embodiments, the conductive structures 421 and 425, and the first shield line 441, the second shield line 443, and the conductive line 445 are formed by a dual-damascene process. The first shield line 441, the second shield line 443 and the conductive line 445 can be formed during the same or different processes. In some embodiments, one or two of the first shield line 441, the second shield line 443 and the conductive line 445 can be formed first, and the others are formed later. In a preferred embodiment, the first shield line 441, the second shield line 443 and the conductive line 445 are formed during the same process. One skilled in the art can readily select the processes in order to obtain desired structures and optimize the process (e.g., with respect to total processing time and/or cost).

FIG. 4C is a cross-sectional view of a semiconductor structure with conductive structures within a second dielectric layer, and a second shield layer over the structure of FIG. 4B.

The second dielectric layer 450 is formed over the structure of FIG. 4B by CVD, PVD or other methods which form thin film layers, for example. The conductive structures 451 and 455 are then formed within the second dielectric layer 450. The steps of forming the conductive structures 451 and 455 are similar to those of forming the conductive structures 421 and 425. Detailed descriptions are not repeated.

The second shield layer 470 is then formed over the surface of the second dielectric layer 450 by CVD, PVD or other methods which are adapted to form thin film layers. In some embodiments, the conductive structures 451 and 455, and the second shield layer 470 are formed by a dual-damascene process. One skilled in the art can readily select the processes in order to achieve a desired structure.

FIGS. 4A-4C show an exemplary method of forming the shield structure shown in FIG. 2D. Based upon the descriptions of steps shown in FIGS. 4A-4C, one skilled in the art can readily understand how to form other exemplary shield structures described in FIGS. 2A-2C and 2E-2F or variations thereof.

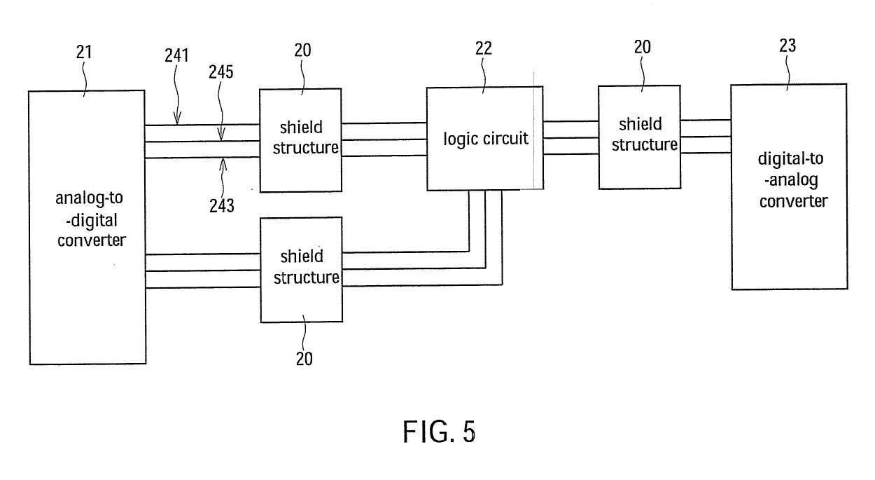

FIG. 5 is a schematic drawing showing an exemplary application of a shield structure among inter-block circuits.

Referring to FIG. 5, the shield structures 20 are configured among various circuits, such as analog-to-digital converter 21, logic circuits 22, digital-to-analog converter 23, or other circuits (not shown) such as amplifiers, oscillator, mixer, charge-pump circuits, converters, input/output (I/O) circuits or other inter-block circuits. In some embodiments, the first shield line 241, the second shield line 243 and the conductive line 245 are coupled to and between any two of the inter-block circuits described above. The length of the first shield line 241, the second shield line 243 and the conductive line 245 is substantially equal to, or less than, the length of wire routing between two inter-block circuits. FIG. 5 merely shows an exemplary application of the shield structure 20. The present invention, however, is not limited thereto. The shield structure 20 can be coupled between circuits exemplarily set forth above. In addition, the number of the shield structure 20 can be selected in a way to constitute a desired circuit. One skilled in the art can readily modify the application of the shield structure 20 and select the number of the shield structure 20 based upon the descriptions set forth above.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

What is claimed is:

1. A semiconductor structure, comprising:
a first shield line and a second shield line coupled with a first voltage formed over a substrate;
at least one conductive line coupled with a second voltage and configured between the first and second shield lines; and
a first shield layer coupled to the first and the second shield lines via at least one first conductive structure over the substrate.

2. The semiconductor structure of claim 1, wherein the first conductive structure comprises at least one via, a conductive line or a combination thereof.

3. The semiconductor structure of claim 1, wherein the conductive line is substantially as long as at least one of the first and second shield lines.

4. The semiconductor structure of claim 1, wherein the conductive line is substantially longer than at least one of the first and second shield lines.

5. The semiconductor structure of claim 1 further comprising a second shield layer over and coupled to the first and second shield lines via at least one second conductive structure.

6. The semiconductor structure of claim 5, wherein the first and second shield lines, the first and second shield layers and the first and second conductive structures substantially surround the conductive line so as to substantially reduce an inductance variation of the conductive line by about 10% or more, relative to another conductive line without the first and second shield layers and the conductive structure.

7. The semiconductor structure of claim 1, wherein dimensions of the semiconductor structure satisfy at least one feature size of a design rule.

8. The semiconductor structure of claim 1 further comprising at least one dummy pattern adjacent to one of the first and the second shield lines.

9. The semiconductor structure of claim 8, wherein the dummy pattern comprises dummy vias or dummy line segments or a combination thereof.

10. The semiconductor structure of claim 8, wherein a space between the dummy pattern and one of the first and the second shield lines is larger than about 0.5 μm.

11. The semiconductor structure of claim 1, wherein the first voltage is ground or a fixed voltage.

12. The semiconductor structure of claim 1, wherein the conductive line comprises a signal line or a power line.

13. A semiconductor structure, comprising:
a signal line above a substrate;
a first shield layer below the signal line; and
a second shield layer over the signal line and coupled to the first shield layer via at least one conductive structure, wherein the first and the second shield layers and the conductive structure substantially surround the signal line so as to substantially reduce an inductance variation of the signal line by about 10% or more, relative to another signal line without the first and second shield layers and the conductive structure.

14. The semiconductor structure of claim 13, wherein dimensions of the semiconductor structure satisfy at least one feature size of a design rule.

15. The semiconductor structure of claim 13, wherein the first and the second ground lines and the signal line are coupled between inter-block circuits.

16. The semiconductor structure of claim 13, further comprising at least one ground line between and coupled to the first and the second shield layers, and adjacent to the signal line.

17. The semiconductor structure of claim 16 further comprising at least one dummy pattern adjacent to the ground lines with a space satisfying at least one feature size of a design rule.

18. A semiconductor structure, comprising:
a first shield line and a second shield line coupled with a first voltage formed over a substrate;
at least one conductive line coupled with a second voltage and configured between the first and second shield lines;
a first shield layer coupled to the first and the second shield lines via at least one conductive structure under the first and second shield lines; and
a second shield layer coupled to the first and the second shield lines via the at least one conductive structure over the first and second shield lines.

19. The semiconductor structure of claim 18, wherein the first voltage is ground or a fixed voltage.

20. The semiconductor structure of claim 18, wherein the conductive line comprises a signal line or a power line.
